(19) United States
(12) Patent Application Publication
(10) Pub. No.: US 2009/0023262 A1
(43) Pub. Date: Jan. 22, 2009

(54) Method for fabricating semiconductor device

(76) Inventors: Cheng-Guo Jin, Osaka (JP); Yuichiro Sasaki, Tokyo (JP); Hiroyuki Ito, Chiba (JP); Bunji Mizuno, Nara (JP)

Correspondence Address: MCDERMOTT WILL & EMERY LLP, 600 13TH STREET, NW, WASHINGTON, DC, 20005-3096, US

(21) Appl. No.: 11/659,197

(22) PCT Filed: Aug. 3, 2005
(86) PCT No.: PCT/JP2005/014220

§ 371 Date: Mar. 7, 2008

(30) Foreign Application Priority Data
Aug. 4, 2004 (JP) 2004-228198

(51) Int. Cl. H01L 21/336

(52) U.S. Cl. 438/303; 257/E21.409

(57) ABSTRACT

To provide a fine transistor of high precision. A method for fabricating a transistor comprises the step of forming a gate electrode (340) on the surface of a semiconductor substrate, the step of introducing an impurity across said gate electrode (340), and the step of activating said impurity, thereby to form a source/drain region (310, 320) in the region having said impurity introduced thereinto. In the transistor fabricating method, the step of introducing said impurity includes a plasma irradiating step. The method further comprises the step of forming, prior to said activating step, a reflection preventing film (400) on the surface of the region having said impurity introduced thereinto, so that the optical reflectivity of said impurity introduced region may be lower than the reflectivity of said gate electrode surface.

### TECHNICAL FIELD

The present invention relates to a method for fabricating a semiconductor device and, more particularly, to an introduction of an impurity into the source/drain region of a transistor and to an activation of the transistor.

### BACKGROUND ART

In recent years, a technique for forming a shallow junction as a semiconductor device becomes finer. In the semiconductor fabricating technique of the prior art, there is widely used a method for ion-injecting impurities of various conduction types such as boron (B), phosphorous (P) or arsenic (As) with a low energy into the surface of a semiconductor substrate as a solid substrate.

Although the shallow junction can be formed by using the ion injection method, there is a limit in the depth which can be formed by the ion injection. For example, the boron impurity is difficult for the shallow introduction, and the ion injection has a limit of about 10 nm in the depth of the introduced region from the substrate surface.

In recent years, therefore, various doping methods have been proposed as a method for making a shallower junction possible. Of these methods, the plasma doping technique is noted as suited for the practical use. This plasma doping is a technique for introducing an impurity by plasma-exciting a reactive gas containing an impurity to be introduced and by plasma-irradiating the reactive gas onto the aforementioned solid substrate surface. After the impurity introduction, moreover, the introduced impurity is activated by an annealing step.

A typical target of a technology node of 45 nm has a sheet resistance of 1,000 Ω/sq or less and a junction depth of 10 nm or less. In order to achieve this target, there is proposed a melt type annealing method using a pulse laser of a high power. An extremely shallow and steep junction can be formed by an instantaneous diffusion in a molten region by melting the impurity introduced layer with a pulse laser. In a field effect transistor, however, a source and a drain having an impurity introduced thereinto are formed near the surface of a solid substrate. A gate insulating film is formed on the substrate between the source and the drain. A gate electrode is formed over the gate insulating film. According to the aforementioned melt type laser annealing method, therefore, the pattern precision is lowered by the deformation of a pattern due to the melting of the gate as well as the activation of the impurity introduced layer and by the melting of a channel portion below the gate insulating film. This causes a problem in the narrowed process window.

For example, there has been proposed a method (as referred to Non-Patent Publication 1) for widening a process window by forming an absorptive layer of a large light absorbing coefficient in the transistor region (e.g., source, drain and gate portions (or a gate insulating film, a gate electrode and a channel)).

There is also proposed a method for a laser-annealing by forming a reflection preventing film on the transistor region. According to this method, the temperature rising rate can be raised (as referred to Patent Publication 1) by reducing the reflectivity of the transistor region covered with the reflection preventing film.

However, both the aforementioned Non-Patent Publication 1 and Patent Publication 1 form either the absorptive layer or the reflection preventing film of the same kind having a homogeneous thickness in the transistor region so that they can enhance the activity factor but invite the temperature rise at the gate portion. As a result, the pattern deformation due to the melting of the gate portion has not reached a solution.

Non-Patent Publication 1: Electrochem. Soc. Sump. Proc., vol. 2000-9 p95-106.

Patent Publication 1: JP-A-2003-168645

### DISCLOSURE OF THE INVENTION

### Problems to be Solved by the Invention

The present invention has been conceived in view of the aforementioned background, and has an object to provide a transistor which is enhanced in precision and in reliability by activating an impurity introduced region, i.e., an impurity introduced layer efficiently and by suppressing the melting of a gate portion.

### Means for Solving the Problems

The invention uses a selective adsorption modulating method as annealing means. Specifically, the optical absorption factor of a gate electrode is made smaller than the absorption factor of a layer having an impurity introduced thereinto, by forming a reflection preventing film selectively on the impurity introduced region and on the gate electrode. It has, therefore, been discovered that both the efficient activation of the impurity introduced layer and the suppression of melting (or non-melting) of the gate portion can be simultaneously realized.

According to the invention, in a method for fabricating a transistor comprising the step of forming a gate electrode on the surface of a semiconductor substrate, the step of introducing an impurity across said gate electrode, and the step of activating said impurity, thereby to form a source/drain region in the region having said impurity introduced thereinto, there is provided a method for fabricating a semiconductor device, which method is characterized in that the step of introducing said impurity includes a plasma irradiating step; and by further comprising the step of forming, prior to said activating step, a reflection preventing film on the surface of the region having said impurity introduced thereinto, so that the optical reflectivity of said impurity introduced region may be lower than the reflectivity of said gate electrode surface.

According to this method, the optically reflection preventing film is selectively formed in the region to become the source/drain region so that the impurity is efficiently activated by optically irradiating the region to become the source/drain region selectively but without the optical irradiation of such a high energy as to melt the gate portion. As a result, the activation of the region having the impurity introduced thereinto and the prevention of the gate portion from being melted can be realized at the same time thereby to form a transistor of high precision and efficiency.

Moreover, the method of the invention further comprises the step of forming, prior to said activating step, a reflecting film on said gate electrode.

According to this method, the reflecting film is formed on the gate electrode so that the absorption of light on the gate electrode can be reduced to realize the prevention of the melting of the gate portion more reliably.

In the method of the invention, moreover, said impurity introducing step includes the step of introducing the impurity by a plasma doping.

According to this method, a shallower source/drain region can be formed, and the region having the impurity doped by the plasma doping can have a higher optical absorptivity so that it can be activated in a higher efficiency. Therefore, the total energy irradiation can be reduced to suppress the melting of the gate portion.

In the method of the invention, moreover, said plasma irradiating step includes the step of making said semiconductor substrate surface amorphous by a plasma irradiation.

According to this method, the amorphous step with the plasma is executed prior to the doping of the impurity so that the optical absorptivity of the impurity introduced region can be raised. Therefore, the activation can be made highly efficient to reduce the total energy irradiation and to suppress the melting of the gate electrode.

In the method of the invention, moreover, said reflection preventing film has different thicknesses in said impurity introduced region and on said gate electrode.

According to this method, the optical absorptivity of the impurity introduced region can be made higher than that on the gate electrode by making the thickness of the reflection preventing film different on the gate electrode and the region to form the source/drain. As a result, the activation can be made highly efficient so that the total energy irradiation can be reduced to suppress the melting of the gate portion.

In the method of the invention, moreover, said activating step includes the step of irradiating a light containing a wavelength from 300 nm to 1,100 nm.

This method is desired because the reflectivity can be lowered by the annealing with the light containing a wavelength from 300 nm to 1,100 nm.

In the method of the invention, moreover, said activating step includes the step of irradiating a light containing a wavelength of 400 nm or less.

According to this method, in case the impurity is doped by the plasma doping, the reflectivity can be desirably made lower by the annealing method using the light containing the wavelength of 400 nm or less.

In the method of the invention, moreover, said reflection preventing film is a transparent film having a refractive index smaller than that of said impurity introduced region.

According to this method, the reflectivity can be lowered by utilizing the interference of the transparent film having a lower refractive index smaller than that of the region corresponding to the impurity introduced source/drain. The transparent film desired for the well matching with the device process and for the usability is exemplified by a silicon oxide film SiO₂, a silicon nitride film Si₃N₄ or a silicon nitric oxide SiON, which is widely employed in the device process of silicon.

In the method of the invention, moreover, said reflection preventing film is a multi-layered dielectric film having two kinds of dielectric films of low/high refractive indices laminated alternately.

The reflectivity is limited in the case of a single SiO2 layer. However, the reflectivity can be the more lowered for the larger lamination number by utilizing the interference of the multi-layered dielectric film having two kinds of dielectric films of low/high refractive indices laminated alternately, so that the reflectivity can be suppressed to a far smaller value.

In the method of the invention, moreover, said reflecting film is a metal film having a melting point of 1,410° C. or higher. According to this constitution, the metal film having a melting point of 1,410° C. or higher is desired because it has a high reflectivity but is hard to melt.

In the method of the invention, moreover, said metal film is tungsten (W), and said activating step includes the step of using a light having a wavelength of 410 nm or more.

In the case of W, the reflectivity is higher than that of the crystal silicon for the light having a wavelength of 410 nm or more.

In the method of the invention, moreover, said metal film is tantalum (Ta), and said activating step includes the step of using a light having a wavelength of 600 nm or more.

In the case of Ta, the reflectivity is higher than that of the crystal silicon for the light having a wavelength of 600 nm or more.

In the method of the invention, moreover, said metal film is titanium nitride (TiN), and said activating step includes the step of using a light having a wavelength of 510 nm or more.

In the case of TiN, the reflectivity is higher than that of the crystal silicon for the light having a wavelength of 510 nm or more.

In the method of the invention, moreover, said reflection preventing film is a silicon oxide film.

By adjusting the film thickness of the silicon oxide, the reflection preventing film can be formed remarkably easily.

### BRIEF DESCRIPTION OF THE DRAWINGS

FIG. 1 is a diagram showing a plasma doping apparatus to be used in Embodiment 1 of the invention.

FIG. 2 is fabrication process diagrams of a transistor in Embodiment 1 of the invention.

FIG. 3 is fabrication process diagrams of a transistor in Embodiment 2 of the invention.

FIG. 4 is a diagram plotting reflectivities against individual wavelengths in transistors, which have reflection preventing films formed after an impurity of boron were introduced by a plasma doping method and an ion injecting method.

FIG. 5 is a diagram plotting reflectivities against individual wavelengths when silicon oxide films are formed after made amorphous by a He plasma and by a Ge ion injection.

FIG. 6 is a diagram plotting a sheet resistance against a laser energy density of the cases, in which a silicon oxide film is not formed and in which a silicon oxide film having a thickness of 85 nm is formed.

FIG. 7 is a diagram plotting a reflectivity against a wavelength of the case, in which films of metals W, Ta and TiN of high melting points are formed on a gate electrode.

### DESCRIPTION OF REFERENCE NUMERALS AND SIGNS

100 Solid Substrate
110 Impurity-introduced Layer
200 Vacuum Chamber
210 Plasma Indicating Rectangle
220 Plasma Source
230 Vacuum Meter
240 Vacuum Pump
250 Power Source
260 Substrate Holder
270 Power Source
280 First Line
290 Second Line
300 Solid Substrate (Silicon Substrate)
310 Impurity-introduced Source Region (Forming Region)
320 Impurity-Introduced Drain Region (Forming Region)
330 Gate Oxide Film
340 Gate Electrode
400 Reflection Preventing Film
410 Highly Reflective Film
500 Annealing Light Source

### BEST MODE FOR CARRYING OUT THE INVENTION

Next, embodiments of the invention are described.

### Embodiment 1

In this embodiment, when a transistor is to be formed on a semiconductor substrate, at the step of introducing an impurity for forming a source/drain region, the impurity is introduced into a silicon substrate surface having a gate electrode formed, by a plasma doping using the gate electrode as a mask. The embodiment is characterized by the step of forming a reflection preventing film, before the impurity is activated by an optical irradiation, so that the optical reflectivity of the region having said impurity introduced thereinto may become low.

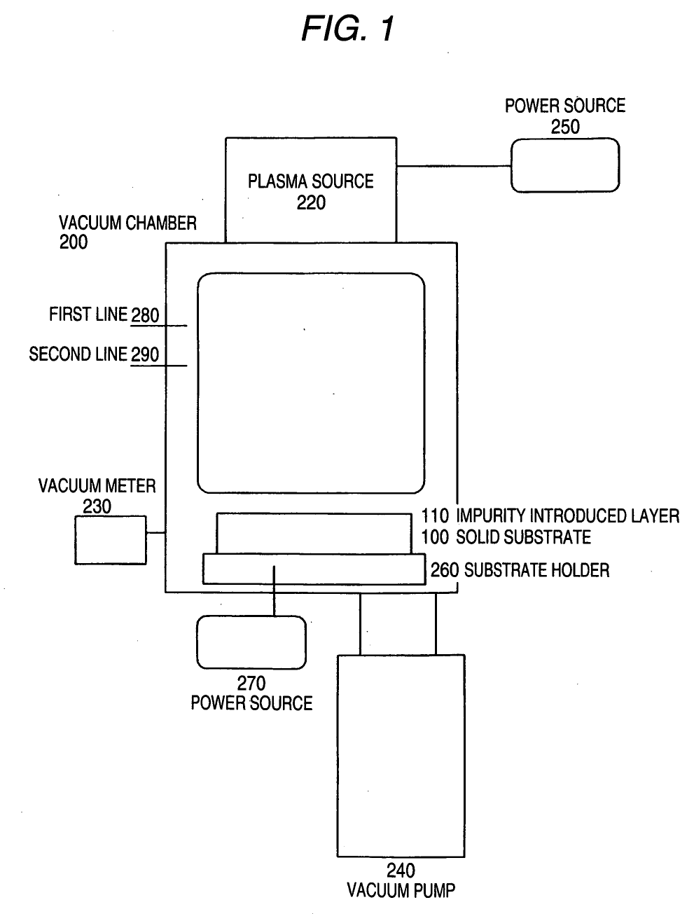

Prior to the description of the process, here are described at first a plasma doping apparatus and an impurity doping process, which are used in a semiconductor device fabricating method used in this embodiment. The doping apparatus to be used in this embodiment is provided, as shown in FIG. 1, with a vacuum chamber 200 and a plasma source 220 for exciting a plasma in the vacuum chamber 200. The doping apparatus performs a plasma doping on the surface of a solid substrate 100 as an object substrate placed on a substrate holder 260.

Moreover, the vacuum chamber 200 is connected with a vacuum pump 240 and is equipped with a vacuum meter 230 for metering the vacuum. A power source 250 is connected with the plasma source 220. With the substrate holder 260, on the other hand, there is connected a power source 270, separately of the aforementioned power source, for applying its own electric potential.

In the vacuum chamber 200, on the other hand, there is disposed a gas introducing mechanism for introducing those gases. This gas introducing mechanism is constituted to include a first line 280 for feeding a first substance (e.g., B₂H₆ in this case) as a dopant substance, and a second line 290 (e.g., He) for feeding another substance, i.e., a second substance.

At first, the dopant substance as the first substance is fed to the vacuum chamber 200. Here, the dopant substance is introduced together with another different substance as a carrier gas. In this embodiment, a gas having properties different from those of the dopant substance is selected as a substance such as a rare gas (different in mass) which is not electrically active in silicon. This substance is He, for example. He is selected as another second substance. The gas is introduced from the gas introduction line composed of the aforementioned first and second lines 280 and 290, and a plasma 210 is generated on the surface of the solid substrate 100 in the vacuum chamber 200.

Charged particles in the plasma are attracted by the electric potential difference between the plasma 210 and the solid substrate 100 thereby to perform an impurity doping. At the same time, an electrically neutral substance sticks to or is occluded by the vicinity of the surface of that solid substrate 100. Here, the state of an impurity introduced layer 110 is so determined by the state of the underlying solid substrate 100 and by the energy owned by the plasma that the impurity introduced layer 110 may stick or may be occluded.

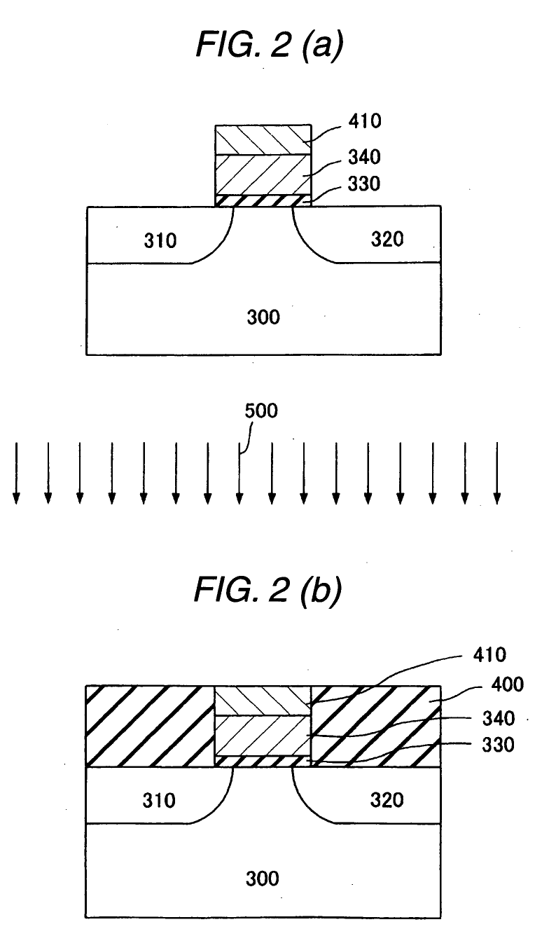

This plasma doping apparatus is used to perform the impurity doping for forming the source/drain region of the transistor. On the surface of a silicon substrate 300, there are formed a gate oxide film 330 formed of a silicon oxide film and a gate electrode 340 of a doped crystalline silicon film. On the gate electrode 340, there is formed a tungsten film (having a thickness of 60 nm) as a reflecting film 410, which is patterned simultaneously with the gate electrode. The setting is made in the plasma doping apparatus shown in FIG. 1, and the plasma-doping is made by using the gate electrode 340 as the mask, as shown in FIG. 2(a).

By a plasma CVD method, a sputtering method or an ion plating method, moreover, a reflection preventing film 400 formed of a silicon oxide film having a thickness of about 90 nm is formed, and the setting is made in the aforementioned annealing apparatus shown in FIG. 1, and the annealing for activation is performed by irradiating a light of a wavelength of 530 nm with an annealing light source 500, as shown in FIG. 2(b). At this time when the silicon oxide film is formed as the reflection preventing film 400, the reflecting film is also formed on the gate electrode. However, the resist used for patterning the gate electrode is left as it is and is lifted off, so that the reflection preventing film is removed from the gate electrode.

Thus, in the presence of the reflection preventing film 400, the light is efficiently introduced into the doped region so that only the plasma-doped region is selectively promoted in heating and proceeded in activation thereby to form the source and drain regions 310 and 320. On the other hand, the surface of the gate electrode 340 is optically irradiated under the reflecting film 410 made of the thin tungsten film having the thickness of about 60 nm so that the light is reflected to suppress a high temperature. Thus, the doped region is selectively annealed for the activation so that the source and drain regions 310 and 320 are efficiently formed while preventing the gate electrode from being melted. Here, the tungsten film has the effect as the reflecting film to suppress the high temperature, as described above, and the effect hard to melt because of a high melting point so that it can activate the source/drain region efficiently and suppress the melting of the gate electrode.

As a result, the impurity introduced layer in the source/drain region can be satisfactorily activated, and the gate electrode and a channel portion can be prevented from being melted, to realize the keeping of shape and quality thereby to realize a fine transistor of high precision and reliability in high yield.

When the reflection preventing film is formed on regions to become the source and drain regions 310 and 320, the silicon oxide film may also be formed to a thickness sufficient for covering the gate electrode and removed from the gate electrode by a CMP or a resist etch-back.

### Embodiment 2

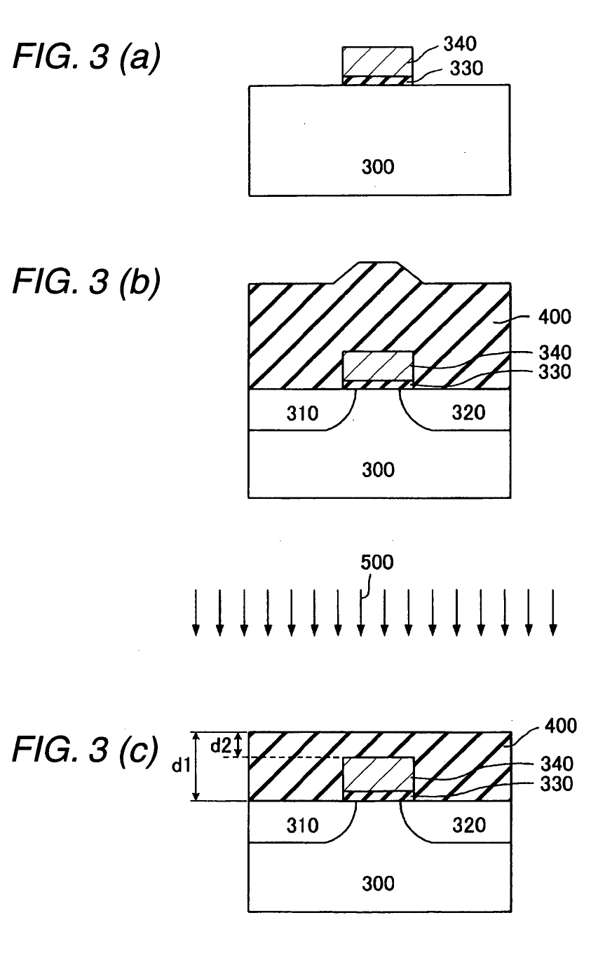

Next, Embodiment 2 of the invention is described. FIGS. 3(a) to (c) are schematic diagrams showing a method of Embodiment 2. In Embodiment 1, the annealing is performed by forming the reflecting film on the gate electrode surface and by forming the silicon oxide film as the reflection preventing film on the semiconductor substrate surface to become the source/drain region. In this embodiment, the reflection preventing film 400 is formed not only on the gate electrode but also on the semiconductor substrate to become the source/drain region, and is made thinner on the gate electrode so that it reduces the optical absorption on the gate electrode thereby to suppress the temperature rise at the gate electrode portion and the melting of the gate.

The gate oxide film 330 made of a silicon oxide film and the gate electrode 340 made of a toped crystal silicon film are formed on the surface of the silicon substrate 300. At this time, the patterning of the gate electrode is performed through a hard mask made of the silicon oxide film 400, and the setting is made in the ordinary plasma doping apparatus without removing the hard mask so that the plasma-doping is performed by using the gate electrode 340 as the mask (FIG. 3(a)).

Then, the reflection preventing film 400 made of the silicon oxide film having a thickness of about 120 is formed at the region to become the source/drain region by the CVD method without removing the hard mask, and the silicon oxide film on the gate electrode is more removed at one portion and flattened by the CMP. As a result, the reflection preventing film 400 formed (FIG. 3(b)) has a smaller thickness d2 on the gate electrode and a larger thickness d1 in the region to become the source/drain region.

In this state, the setting is made in the aforementioned annealing apparatus shown in FIG. 1, and the activation (FIG. 3(c)) is effected by using the annealing light source having the wavelength of 530 nm.

As a result, the activation of the impurity introduced layer in the source/drain region can be realized without melting the gate electrode and the channel, thereby to realize a fine transistor of high precision and reliability in high yield.

In the aforementioned embodiment, while the silicon oxide film used as the hard mask being left, the silicon oxide film is formed over that silicon oxide film and is flattened by the CMP so that it is made thick on the source/drain region but thin on the gate electrode. By patterning the gate electrode without using the hard mask, however, the reflection preventing film made of the silicon oxide film may also be formed by a similar process.

Moreover, a two-layered film of a silicon oxide film and a silicon nitride film may also be used as the hard mask. Specifically, the patterning of the gate electrode is performed through the hard mask of the two-layered film of the silicon oxide film and the silicon nitride film. The setting is made in the ordinary plasma doping apparatus without removing the hard mask, and the plasma-doping is performed by using that gate electrode 340 as the mask.

Then, the reflection preventing film 400 made of the silicon oxide film having the thickness of about 90 nm is formed by the CVD method or the like in the region to become the source/drain region without removing the hard mask. After this, the silicon nitride film or the film over the hard mask is removed, and the reflection preventing film 400 on the gate electrode is also lifted off. As a result, the reflection preventing film formed can have the smaller thickness d2 on the gate electrode and the larger thickness d1 (d1>d2) in the region to become the source/drain region.

Moreover, the annealing may also be performed while the silicon nitride film being left, if necessary.

Thus, the reflection preventing film 400 having the thickness d1 is formed on the region to become the source region 310 and the drain region 320, and the reflection preventing film 400 having the thickness d2 is formed on the gate electrode 340 thereby to activate the annealing light source 500. By designing the thicknesses d1 and d2 so that the reflectivity on the region surface to become the source/drain region may be lower than that on the gate electrode, therefore, the keeping of the high precision of the gate size can be realized together with the satisfactory activation of the impurity introduced layer of the source/drain region.

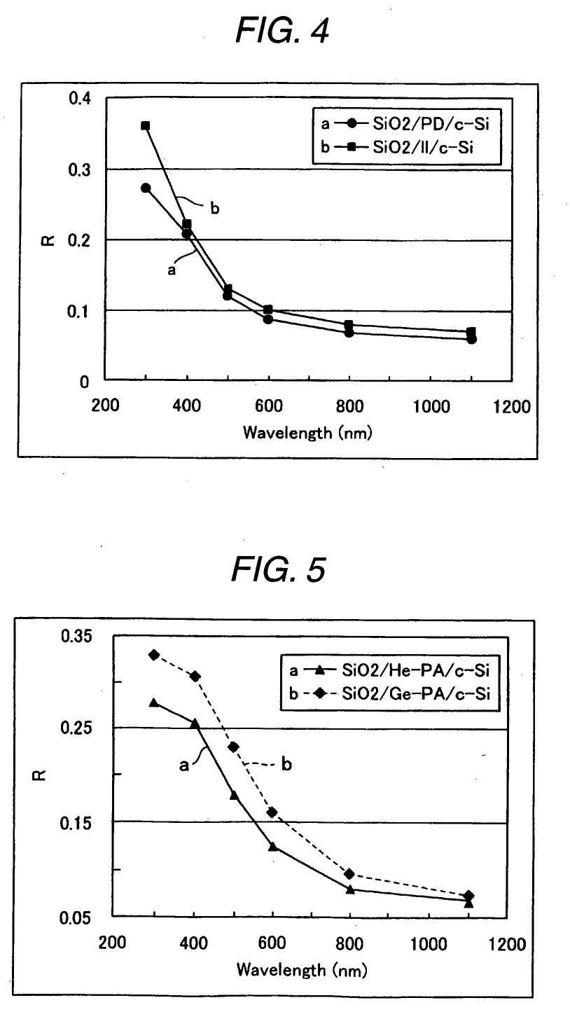

The calculated values of the reflectivity against the individual wavelengths are plotted, as indicated by curves a and b in FIG. 4, in case the silicon oxide films were formed as the reflection preventing film by introducing boron as the impurity individually by the plasma doping (as indicated by PD) and the ion injection (II). The optically physical values of the PD layer and the II layer of the same dose (6E14 cm²) were measured, and the reflectivities were calculated with a multi-layer calculation software. It is found that the PD method is preferable in the wavelength range of 400 nm or less because it can attain a lower reflectivity than the II method.

### Embodiment 3

Next, in Embodiment 3 of the invention, the step of making amorphous is executed before the step of introducing the impurity by the plasma. As a result, it is possible to raise the optical absorptivity of the region having the impurity introduced thereinto.

In this embodiment, before the step of introducing the impurity by the plasma, i.e., the plasma doping step, the surfaces of the regions to have the impurity introduced thereinto are made amorphous in advance to lower the reflectivities. Specifically, the regions are individually made amorphous by the He plasma (as expressed by He—PA) and by the Ge ion injection (as expressed by Ge—PA), and the silicon oxide film is then formed as the reflection preventing film. Subsequently, the doping is performed as in the aforementioned Embodiments 1 and 2. The remaining procedures are similar to those of the aforementioned Embodiments 1 and 2.

In FIG. 5, the relations of the reflectivities against the individual wavelength of the doped surface of the cases, in which the silicon oxide films were individually formed after made amorphous by the He plasma (as expressed by He—PA) and the Ge ion injection (as expressed by Ge—PA), are plotted by curves a and b. Here, the reflectivities used are calculated on the basis of the film thickness. Here the optically physical values of the He—PA layer and the Ge—PA layer of the amorphous layers of the same depth (12 nm) were measured, and the reflectivities were calculated with the multi-layer calculation software. It is found that the He—PA method is more effective in the wavelength range from 300 nm to 1,100 nm because it can attain a lower reflectivity than the Ge—PA method.

### Embodiment 4

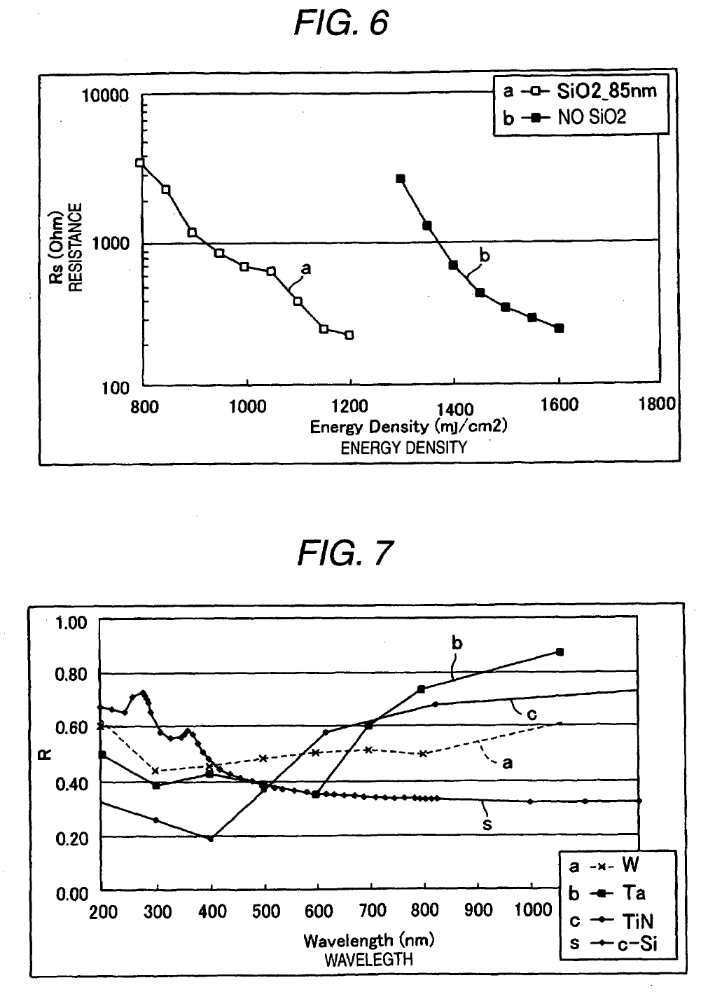

Next, in Embodiment 4 of the invention, in order to confirm the change in the state after the annealing step between the presence and absence of the reflection preventing film, the impurity boron was introduced by the plasma doping method into an n-type silicon substrate, and a silicon oxide film having a thickness of 90 nm was formed on the n-type silicon substrate by the plasma CVD method. After this, the silicon oxide film was annealed by the laser having a wavelength of 530 nm. The results of the sheet resistances against the laser energy densities of the cases, in which the silicon oxide film was not formed and in which the silicon oxide film was formed to have the thickness of 90 nm, are plotted by curves a and b in FIG. 6. By forming the silicon oxide film having the thickness of 90 nm, the energy density capable of attaining a sheet resistance of 340 ohms/sq could be reduced from 1,500 mJ/cm² to 1,100 mJ/cm². The reduction ratio of the energy density was about 27%. This result implies that the reflectivity can be adjusted by adjusting the thickness of the silicon oxide film or the reflection preventing film.

### Embodiment 5

Next, in Embodiment 5 of the invention, there are plotted the calculated values of the reflectivities against the wavelength of the cases, in which a tungsten W layer, a tantalum Ta layer and a titanium nitride TiN film were formed as metal layers on the surface of the gate electrode. In FIG. 7, curves a, b and C indicate the results of measurement of the relations of the reflectivities against the wavelengths individually for W, Ta and TiN. For comparison, the reflectivities against the individual wavelengths of the crystalline silicon (c-Si) are also plotted by a curve s. In case the metals W, Ta and TiN having high melting points were applied to the gate electrode, high reflectivities could be attained individually for the wavelengths 410 nm, 600 nm and 510 nm than the crystalline silicon making the gate electrode.

After the source/drain region was formed, it is necessary to form source/drain contacts. However, the step of removing the reflection preventing film later can be eliminated by exemplifying the reflection preventing film by a conductive layer which can be the source/drain contact.

### INDUSTRIAL APPLICABILITY

The method of the invention for fabricating the transistor by using the selective adsorption modulation is effective for forming a junction of a shallow and low resistor, for reducing an activation energy, for lowering an annealing temperature and for preventing a gate deformation.

1. A method for fabricating a transistor comprising the step of:
forming a gate electrode on the surface of a semiconductor substrate;
introducing an impurity across said gate electrode;
activating said impurity so as to form a source/drain region in the region having said impurity introduced thereinto; and
forming, prior to said activating step, a reflection preventing film on the surface of the region having said impurity introduced thereinto, so that the optical reflectivity of said impurity introduced region can be lower than the reflectivity of said gate electrode surface
wherein the step of introducing said impurity includes a plasma irradiating step.

2. The method for fabricating a semiconductor device as set forth in claim 1, further comprising:
forming, prior to said activating step, a reflecting film on said gate electrode.

3. The method for fabricating a semiconductor device as set forth in claim 1, wherein said impurity introducing step includes the step of introducing the impurity by a plasma doping.

4. The method for fabricating a semiconductor device as set forth in claim 1, wherein said plasma irradiating step includes the step of making said semiconductor substrate surface amorphous by a plasma irradiation.

5. The method for fabricating a semiconductor device as set forth in claim 1, wherein said reflection preventing film has different thicknesses in said impurity introduced region and on said gate electrode.

6. The method for fabricating a semiconductor device as set forth in claim 1, wherein said activating step includes the step of irradiating a light containing a wavelength from 300 nm to 1,100 nm.

7. The method for fabricating a semiconductor device as set forth in claim 1, wherein said activating step includes the step of irradiating a light containing a wavelength of 400 nm or less.

8. The method for fabricating a semiconductor device as set forth in claim 1, wherein said reflection preventing film is a transparent film having a refractive index smaller than that of said impurity introduced region.

9. The method for fabricating a semiconductor device as set forth in claim 1, wherein said reflection preventing film is a multi-layered dielectric film having two kinds of dielectric films of low/high refractive indices laminated alternately.

10. The method for fabricating a semiconductor device as set forth in claim 2, wherein said reflecting film is a metal film having a melting point of 1,410° C. or higher.

11. The method for fabricating a semiconductor device as set forth in claim 10, wherein said metal film is tungsten (W), and said activating step includes the step of using a light having a wavelength of 410 nm or more.

12. The method for fabricating a semiconductor device as set forth in claim 11, wherein said metal film is tantalum (Ta), and said activating step includes the step of using a light having a wavelength of 600 nm or more.

13. The method for fabricating a semiconductor device as set forth in claim 11, wherein said metal film is titanium nitride (TiN), and said activating step includes the step of using a light having a wavelength of 510 nm or more.

14. The method for fabricating a semiconductor device as set forth in claim 5, wherein said reflection preventing film is a silicon oxide film.
